(19) United States
(12) Patent Application Publication
(10) Pub. No.: US 2024/0196624 A1
(43) Pub. Date: Jun. 13, 2024

(54) METHOD OF MANUFACTURING FERROELECTRIC-BASED 3-DIMENSIONAL FLASH MEMORY

(71) Applicant: SAMSUNG ELECTRONICS CO., LTD., SUWON-SI, GYEONGGI-DO (KR)

(72) Inventors: Yunheub SONG, SUWON-SI, GYEONGGI-DO (KR); CHANGHWAN CHOI, SUWON-SI, GYEONGGI-DO (KR); JAEMIN SIM, SUWON-SI, GYEONGGI-DO (KR)

(21) Appl. No.: 18/554,032

(22) PCT Filed: Mar. 25, 2022
(86) PCT No.: PCT/KR2022/004188

§ 371 Date: Oct. 5, 2023

(30) Foreign Application Priority Data
Apr. 5, 2021 (KR) 10-2021-0043751
Feb. 7, 2022 (KR) 10-2022-0015410

(51) Int. Cl. H10B 51/20; H01L 29/66; H01L 29/78

(52) U.S. Cl. CPC H10B 51/20; H01L 29/6684; H01L 29/78391

(57) ABSTRACT

A method of manufacturing a ferroelectric-based 3-dimensional flash memory is disclosed. Also, a 3-dimensional flash memory that improves ferroelectric polarization properties and a method of manufacturing the same are disclosed.

### TECHNICAL FIELD

Embodiments below relate to a 3-dimensional flash memory, and more particularly, to a technique related to a method of manufacturing a ferroelectric-based 3-dimensional flash memory.

### BACKGROUND ART

A flash memory is an electrically erasable programmable read-only memory (EEPROM) and, since input and output of data to and from a flash memory may be electrically controlled through Fowler-Nordheim (F-N) tunneling or hot electron injection, the flash memory may be commonly used in computers, digital cameras, MP3 players, game systems, memory sticks, etc.

Such a flash memory has recently been developed into a 3-dimensional structure stacked vertically, and a structure using a ferroelectric layer as a charge storage layer is being researched and developed. For example, referring to FIG. 1 showing a conventional ferroelectric layer-based 3-dimensional flash memory, a 3-dimensional flash memory 100 has a 3-dimensional structure including a substrate 105, a plurality of word lines 110 stacked on the substrate 105, a plurality of interlayer insulation layers 120 interposed between the plurality of word lines 110, and at least one cell string 130 penetrating through the plurality of word line 110 and the plurality of interlayer insulation layers 120 and including a channel layer 131 and a charge storage layer 132.

In this structure, when a ferroelectric layer is used as the charge storage layer 132, a technique of performing a rapid cooling process while a TiN barrier metal layer 140 is deposited on the top or the bottom of the plurality of word lines 110 to improve the ferroelectric properties of the ferroelectric layer has been proposed. The technique is based on the principle that the ferroelectric properties of the charge storage layer 132, which is a ferroelectric layer, are improved by changes in stress with respect to the barrier metal layer 140.

However, the existing technology has the problem of insufficient stress effect due to a small contact area between the barrier metal layer 140 and the charge storage layer 132, which is a ferroelectric layer, and the complicated and difficult process of applying the barrier metal layer to a 3-dimensional structure.

Therefore, a technique to resolve the above-stated problems and shortcomings need to be proposed.

Also, in a structure using a ferroelectric-based data storage pattern, orthorhombic properties thereof may be improved by performing a cooling process while the data storage pattern is contacting a word line.

However, since a word line replacement process is used in the conventional 3-dimensional flash memory manufacturing method, word lines are formed by removing sacrificial layers, after a ferroelectric-based data storage pattern is formed and a vertical channel pattern is formed therein.

Therefore, in the conventional method of manufacturing a 3-dimensional flash memory, even when a cooling process is performed, stress cannot be generated between the word lines and the data storage pattern, and thus the orthorhombic properties of the data storage pattern cannot be improved.

Therefore, a technique to improve the orthorhombic properties of a ferroelectric-based data storage pattern even when the word line replacement process is used needs to be proposed.

### DISCLOSURE

### Technical Problem

Embodiments propose a method of manufacturing a 3-dimensional flash memory using a semiconductor structure in which a barrier metal layer and a ferroelectric layer extend in contact with each other in a vertical direction to resolve the insufficient stress effect due to a small contact area between the barrier metal layer and the ferroelectric layer and the complicated and difficult process of applying the barrier metal layer to a 3-dimensional structure.

Also, embodiments propose a 3-dimensional flash memory for improving the orthorhombic properties of a ferroelectric-based data storage pattern even when using a word line replacement process, and a method of manufacturing the same.

In detail, embodiments propose a 3-dimensional flash memory including a stress control pattern used for generating stress with respect to a data storage pattern to improve the orthorhombic properties of the data storage pattern, and a method of manufacturing the same.

However, the technical goals to be achieved by the present disclosure are not limited to the above-stated goals and may be variously extended without departing from the spirit and scope of the present disclosure.

### Technical Solution

According to an embodiment, a method of manufacturing a ferroelectric-based 3-dimensional flash memory, the method includes preparing a semiconductor structure including a plurality of word lines extending in a horizontal direction and stacked in a vertical direction on a substrate, a plurality of sacrificial layers interposed between the plurality of word lines and extending in the horizontal direction, and at least one hole formed to extend in the vertical direction and penetrate through the plurality of word lines and the plurality of sacrificial layers, wherein a barrier metal layer extending in the vertical direction is deposited on an inner wall of the at least one hole, and a ferroelectric layer used as a charge storage layer is deposited on an inner wall of the barrier metal layer, performing a rapid cooling process on the ferroelectric layer in the semiconductor structure, forming a channel layer to extend in the vertical direction on an inner wall of the ferroelectric layer, removing the plurality of sacrificial layers, and forming barrier metal regions isolated from one another by removing portions of the barrier metal layer through spaces formed by removing the plurality of sacrificial layers.

In the performing of the rapid cooling process, based on that the ferroelectric properties of the ferroelectric layer, which are improved through the rapid cooling process, is improved in proportion to a contact area of the barrier metal layer in contact with the ferroelectric layer during the rapid cooling process, the rapid cooling process may be performed to maximize the ferroelectric properties of the ferroelectric layer through the barrier metal layer in contact with an entire area of one surface of the ferroelectric layer.

The removing of the plurality of sacrificial layers and the forming of the barrier metal regions isolated from one another may be simultaneously performed as removal of the plurality of sacrificial layers and removal of the portions of the barrier metal layer are performed together.

The forming of the barrier metal regions isolated from one another may include removing the portions of the barrier metal layer corresponding to the plurality of sacrificial layers among an entire area of the barrier metal layer.

The removing of the plurality of sacrificial layers may include forming a plurality of air gaps that insulate the plurality of word lines from one another.

According to an embodiment, a 3-dimensional flash memory includes interlayer insulation layers and word lines extending in horizontal directions and alternately stacked in a vertical direction, and vertical channel structures extending and penetrating through the interlayer insulation layers and the word lines in the vertical direction, wherein each of the vertical channel structures includes a vertical channel pattern extending in the vertical direction, a ferroelectric-based data storage pattern surrounding an outer wall of the vertical channel pattern, and a stress control pattern contacting an outer side wall of the data storage pattern, wherein the stress control pattern is used to generate stress with respect to the data storage pattern so as to improve orthorhombic properties of the data storage pattern.

The stress control pattern may be formed to extend in the vertical direction to be interposed between each of the interlayer insulation layers and the data storage pattern, and between each of the word lines and the data storage pattern.

The stress control pattern may be formed in a separated structure in correspondence to the interlayer insulation layers and to be separated in the vertical direction to be interposed between each of the interlayer insulation layers and the data storage pattern.

According to an embodiment, a method of manufacturing a 3-dimensional flash memory, the method includes preparing a semiconductor structure including interlayer insulation layers and sacrificial layers extending in horizontal directions and alternately stacked in a vertical direction, forming channel holes to extend in the vertical direction in the semiconductor structure, forming vertical channel structures to extend in the vertical direction, the vertical channel structures each including a stress control pattern, a ferroelectric-based data storage pattern, and a vertical channel pattern, in the channel holes, improving orthorhombic properties of the data storage pattern by generating stress between the stress control pattern and the data storage pattern, removing the sacrificial layers, and forming word lines in spaces formed by removing the sacrificial layers.

The removing of the sacrificial layers may include removing portions of the stress control pattern through the spaces formed by removing the sacrificial layers, and the forming of the word lines may include forming the word lines even in spaces formed by removing the portions of the stress control pattern.

### Advantageous Effects

Embodiments propose a method of manufacturing a 3-dimensional flash memory using a semiconductor structure in which a barrier metal layer and a ferroelectric layer extend in contact with each other in a vertical direction to resolve the insufficient stress effect due to a small contact area between the barrier metal layer and the ferroelectric layer and the complicated and difficult process of applying the barrier metal layer to a 3-dimensional structure.

Also, embodiments propose a 3-dimensional flash memory for improving the orthorhombic properties of a ferroelectric-based data storage pattern even when using a word line replacement process, and a method of manufacturing the same.

In detail, embodiments propose a 3-dimensional flash memory including a stress control pattern used for generating stress with respect to a data storage pattern to improve the orthorhombic properties of the data storage pattern, and a method of manufacturing the same.

However, the effects of the present disclosure are not limited to the above-stated effects and may be variously extended without departing from the spirit and scope of the present disclosure.

### DESCRIPTION OF DRAWINGS

FIG. 1 is a side cross-sectional view of a conventional 3-dimensional flash memory.

FIG. 2 is a flowchart of a method of manufacturing a 3-dimensional flash memory according to an embodiment.

FIGS. 3A to 3D are side cross-sectional views of a 3-dimensional flash memory for describing the method shown in FIG. 2.

FIGS. 4A and 4B are diagrams showing portions of a 3-dimensional flash memory to illustrate the excellence of the method shown in FIG. 2.

FIG. 5 is a simplified circuit diagram showing an array of 3-dimensional flash memory according to an embodiment.

FIG. 6 is a side cross-sectional view of the structure of a 3-dimensional flash memory according to an embodiment.

FIG. 7 is a side cross-sectional view of the structure of a 3-dimensional flash memory according to another embodiment.

FIG. 8 is a flowchart of a method of manufacturing a 3-dimensional flash memory according to an embodiment.

FIGS. 9A to 9F are side cross-sectional views of a 3-dimensional flash memory for describing the method shown in FIG. 8.

### MODE FOR INVENTION

Hereinafter, embodiments of the present disclosure will be described with reference to the accompanying drawings. However, the present disclosure is not limited to the embodiments. Also, the same reference numerals in the drawings denote the same elements.

Additionally, terminologies used in this specification are terms used to appropriately express preferred embodiments of the present disclosure, and may vary depending on the intention of a viewer and/or an operator or customs in the field to which the present disclosure belongs. Therefore, definitions of these terms should be made based on the content throughout this specification. For example, as used herein, the singular forms “a,” “an” and “the” are intended to include the plural forms as well, unless the context clearly indicates otherwise. Also, it will be further understood that the terms “comprises” and/or “comprising” used herein specify the presence of stated features or components, but do not preclude the presence or addition of one or more other features or components.

Also, it is to be understood that the various embodiments of the disclosure are different but need not be mutually exclusive. For example, certain shapes, structures, and characteristics described herein may be implemented in other embodiments without departing from the spirit and scope of the present disclosure in connection with one embodiment. Also, it is to be understood that the position, arrangement, or configuration of individual components in each of embodiments may be changed without departing from the spirit and scope of the present disclosure.

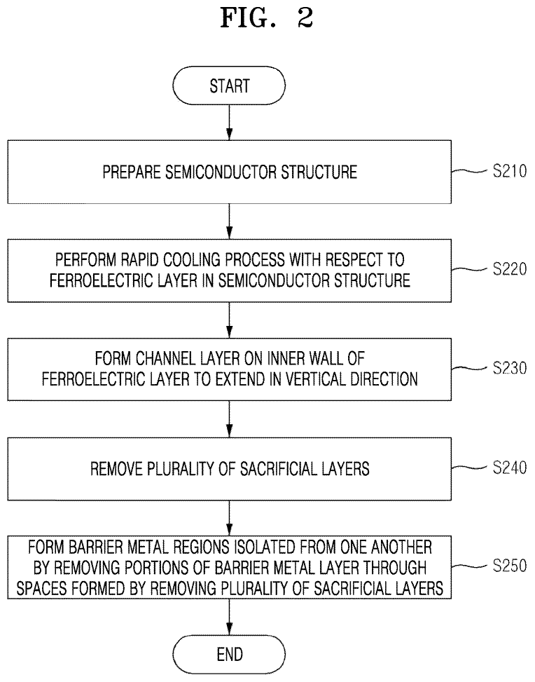

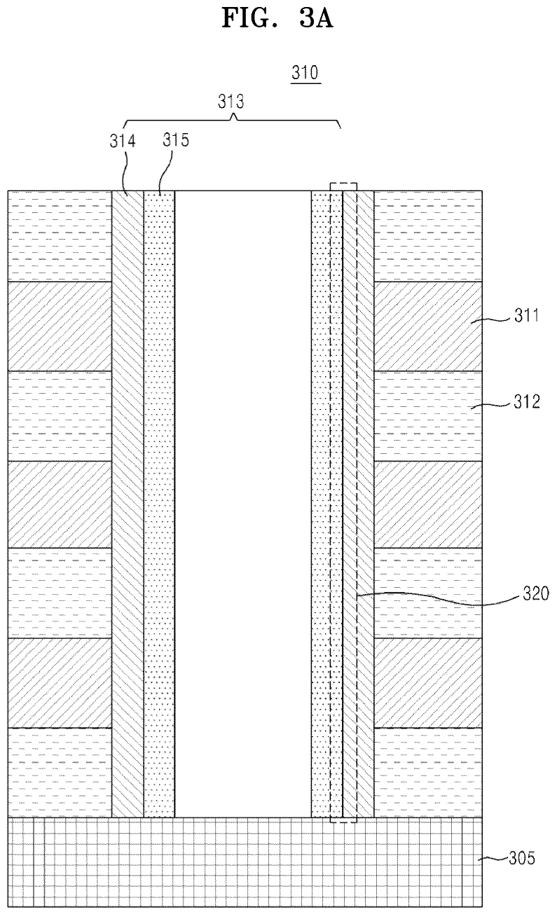

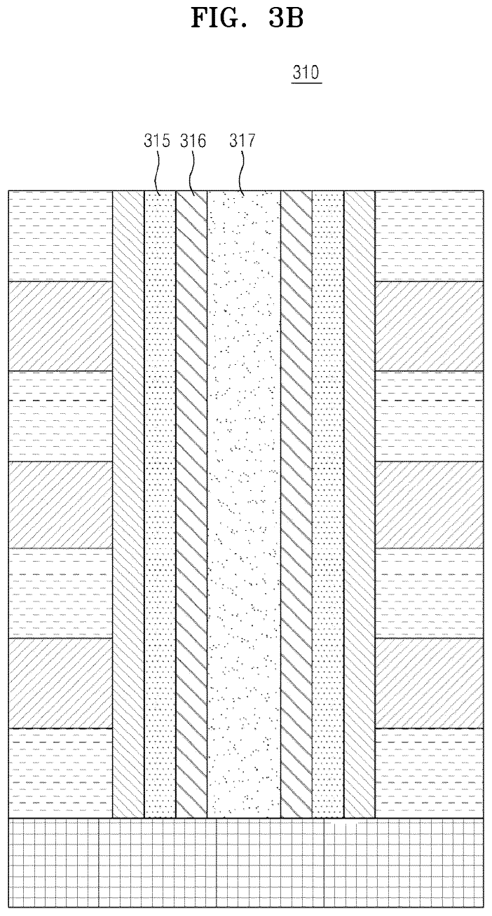

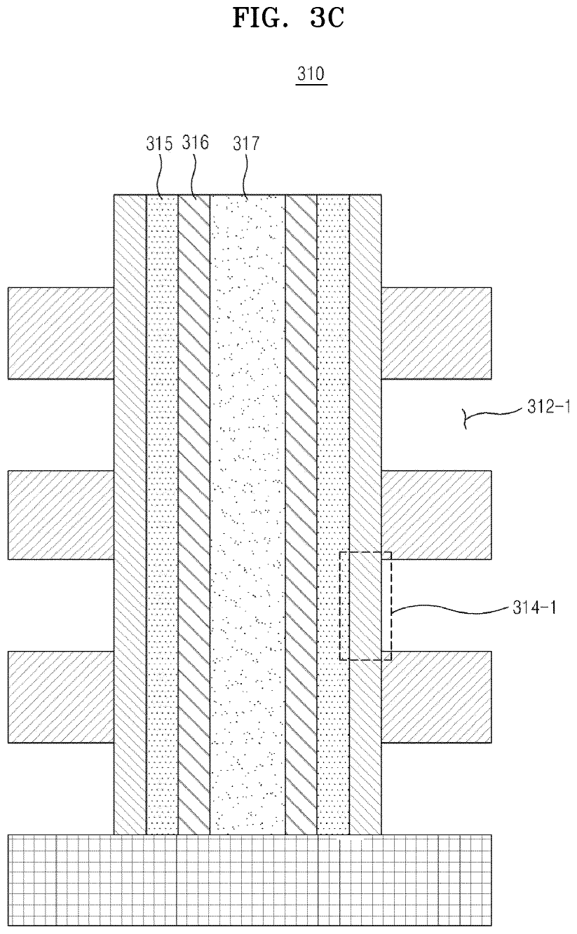

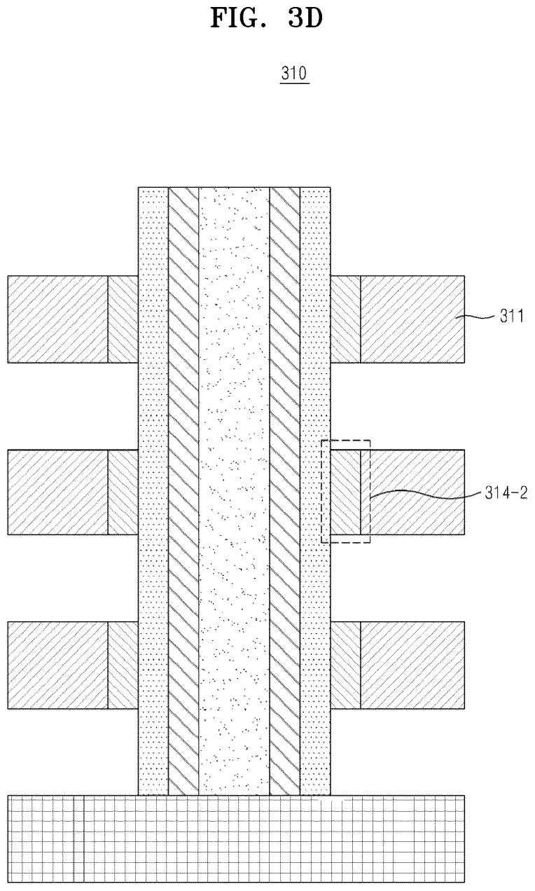

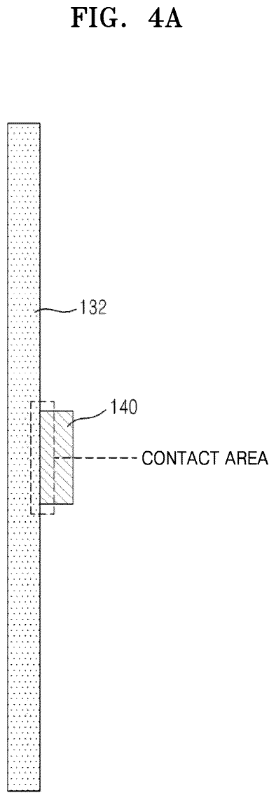

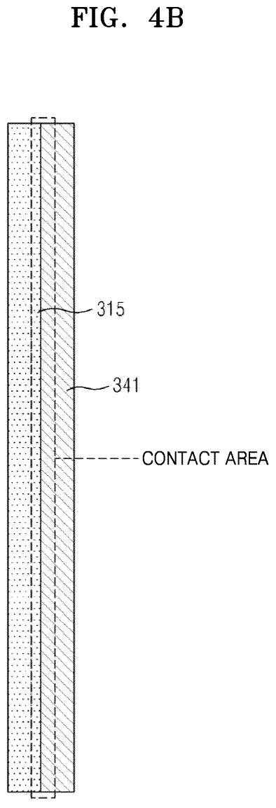

FIG. 2 is a flowchart of a method of manufacturing a 3-dimensional flash memory according to an embodiment, FIGS. 3A to 3D are side cross-sectional views of a 3-dimensional flash memory to describe the manufacturing method shown in FIG. 2, and FIGS. 4A and 4B are diagrams showing a portion of a 3-dimensional flash memory to describe the excellence of the manufacturing method shown in FIG. 2. Hereinafter, the subject of the manufacturing method is an automated and mechanized manufacturing system, and a product that is completed as a result of performing the manufacturing method may be a 3-dimensional flash memory 300 shown with reference to FIG. 4B.

In operation S210, the manufacturing system may prepare a semiconductor structure 310 as shown in FIG. 3A.

Here, the semiconductor structure 310 may include a plurality of word lines 311, a plurality of sacrificial layers 312, and at least one hole 313.

The plurality of word lines 311 are formed to extend in a horizontal direction on a substrate 305, are sequentially stacked in a vertical direction, and may each include a conductive material such as tungsten (W), titanium (Ti), tantalum (Ta), copper (Cu), molybdenum (Mo), ruthenium (Ru), or gold (Au) (including all other metal materials that may be formed through an atomic layer deposition (ALD) process) to apply a voltage to a corresponding memory cell to perform a memory operation (e.g., a read operation, a program operation, and an erase operation, and the like). String select lines SSL may be arranged at the top of the plurality of word lines 311, and ground select lines GSL may be arranged below the plurality of word lines 311.

The plurality of sacrificial layers 312 may be interposed between the plurality of word lines 311 and may extend in the horizontal direction. Here, the plurality of sacrificial layers 312 may be formed of a material that may be removed through an etching process in operation S240, which will be described later.

At least one hole 313 is a component extending vertically through the plurality of word lines 311 and the plurality of sacrificial layers 312, and a barrier metal layer 314 extending in the vertical direction may be deposited on the inner wall of the at least one hole 313. A ferroelectric layer used as a charge storage layer 315 may be deposited on the inner wall of the barrier metal layer 314.

Here, the barrier metal layer 314 may be formed of TiN, and a ferroelectric layer 315 may include a ferroelectric material including at least one of HfOₓ having an orthorhombic crystal structure, HfOₓ doped with at least one from among Al, Zr, or Si, PZT(Pb(Zr, Ti)O₃), PTO(PbTiO₃), SBT(SrBi₂Ti₂O₃), BLT(Bi(La, Ti)O₃), PLZT(Pb(La, Zr)TiO₃), BST(Bi(Sr. Ti)O₃), barium titanate (BaTiO₃), P(VDF-TrFE), PVDF, AlOₓ, ZnOₓ, TiOₓ, TaOₓ, and InOₓ.

The ferroelectric layer 315 is a component that maintains the state (e.g., polarization state) of charges due to a voltage applied through the plurality of word lines 311 and may serve as a data storage of the 3-dimensional flash memory 300. Therefore, the ferroelectric layer 315, together with a channel layer 316 formed after operation S250, may constitute a plurality of memory cells corresponding to the plurality of word lines 311.

In particular, the barrier metal layer 314 extends in the same vertical direction as the ferroelectric layer 315, thereby contacting the entire area of one surface of the ferroelectric layer 315. This is to improve the efficiency of the rapid cooling process in operation S220, which will be described later.

Next, in operation S220, the manufacturing system may perform a rapid cooling process for the ferroelectric layer 315 in the semiconductor structure 310. Here, the environmental conditions of the rapid cooling process may be the same as those of the rapid cooling process for improving the ferroelectric properties of a conventional ferroelectric layer.

However, the manufacturing method according to an embodiment is significantly different from the rapid cooling process for improving the ferroelectric properties of a conventional ferroelectric layer in that, as the semiconductor structure 310 in which the barrier metal layer 314 contacts the entire area of one surface of the ferroelectric layer 315 is prepared in operation S210, a rapid cooling process is performed on the ferroelectric layer 315 having the maximized contact area with the barrier metal layer 314.

In other words, the manufacturing system may perform a rapid cooling process to maximize the ferroelectric properties of the ferroelectric layer 315 through the barrier metal layer 314 by preparing a structure in which the barrier metal layer 314 contacts the entire area of one surface of the ferroelectric layer 315 based on the fact that the ferroelectric properties of the ferroelectric layer 315 are improved through the rapid cooling process in proportion to the contact area of the barrier metal layer 314 in contact with the ferroelectric layer 315 during the rapid cooling process.

In a next operation (operation S230), the manufacturing system may form the channel layer 316 extending in the vertical direction on the inner wall of the ferroelectric layer 315, as shown in FIG. 3B.

Also, although not shown as a separate operation, the manufacturing system may fill the inner wall of the channel layer 316 with a buried film 317.

In a next operation (operation S240), the manufacturing system may remove the plurality of sacrificial layers 312 as shown in FIG. 3C. By removing the plurality of sacrificial layers 312 in this way, the manufacturing system may form a plurality of air gaps in spaces 312-1 formed by removing the plurality of sacrificial layers 312. The plurality of air gaps are components that insulate the plurality of word lines 311 from one another and may be filled with a gas such as air. However, the present disclosure is not limited thereto, and the plurality of air gaps may be maintained in a vacuum state.

Thereafter, in operation S250, as shown in FIG. 3D, the manufacturing system may form barrier metal regions 314-2 isolated from one another by removing portions 314-1 of the barrier metal layer 314 through the spaces 312-1 formed by removing the plurality of sacrificial layers 312. For example, the manufacturing system may form the barrier metal regions 314-2 isolated from one another by removing the portions 314-1 of the barrier metal layer 314 corresponding to the plurality of sacrificial layers 312 to leave only portions 314-2 corresponding to the plurality of word lines 311.

The barrier metal regions 314-2 are isolated from one another in this way, such that a plurality of memory cells are electrically isolated from one another in correspondence to the plurality of word lines 311.

Here, in operations S240 and S250, the plurality of sacrificial layers 312 are removed and the portions 314-1 of the barrier metal layer 314 may be removed at the same time. In other words, the manufacturing system may remove the plurality of sacrificial layers 312 and the portions 314-1 of the barrier metal layer 314 at the same time through a single etching process.

The 3-dimensional flash memory 300, which is manufactured through operations S210 to S250, ultimately has a structure as shown in FIG. 4b, and, since a rapid cooling process is performed on the ferroelectric layer 315 of which an entire one surface contacts the barrier metal layer 314 through operations S210 and S220, may include the ferroelectric layer 315 having maximized ferroelectric properties.

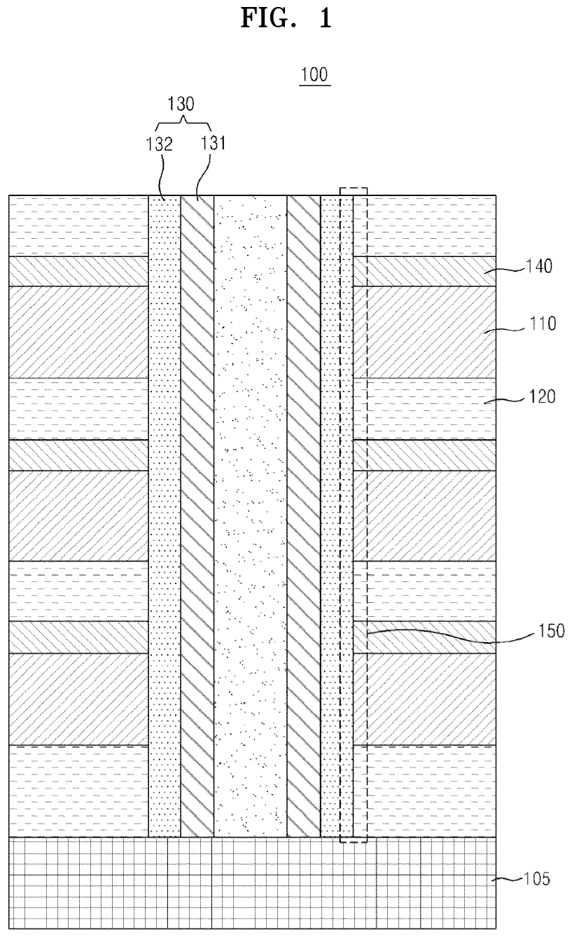

In other words, in the rapid cooling process for improving the ferroelectric properties of a conventional ferroelectric layer, since a barrier metal layer 140 is in contact with a ferroelectric layer 132 through a very small area, as shown in FIG. 4A showing a region 150 of FIG. 1, the degree of improvement in the ferroelectric properties of the ferroelectric layer 132 is very small. Meanwhile, in the manufacturing method according to an embodiment, the barrier metal layer 314 contacts the entire area of one surface of the ferroelectric layer 315 as shown in FIG. 4B showing a region 320 of FIG. 3A, the degree of improvement in the ferroelectric properties of the ferroelectric layer 315 may be maximized.

In the side cross-sectional view if the 3-dimensional flash memory 300 manufactured by performing the above-stated manufacturing method, a 3-dimensional flash memory is illustrated while components such as source lines located at the bottom of a plurality of cell strings are omitted for convenience of explanation. Therefore, it is obvious that the 3-dimensional flash memory 300 manufactured by performing the manufacturing method may further include additional components required in the existing 3D structure.

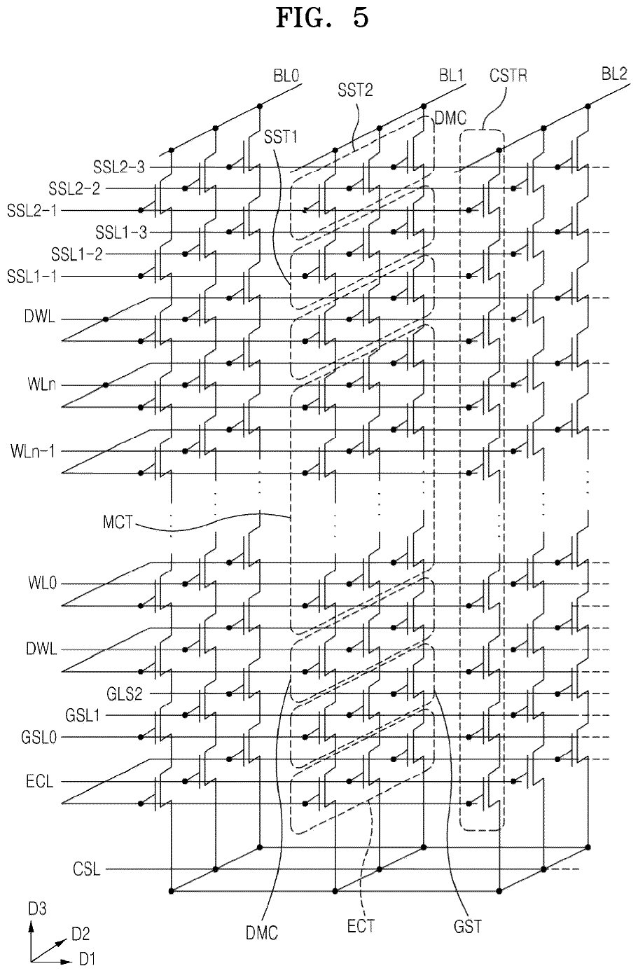

FIG. 5 is a simplified circuit diagram showing an array of 3-dimensional flash memory according to an embodiment.

Referring to FIG. 5, an array of a 3-dimensional flash memory according to an embodiment may include a common source line CSL, a plurality of bit lines BL0, BL1, and BL2, and a plurality of cell strings CSTR arranged between the common source line CSL and the bit lines BL0, BL1, and BL2.

The bit lines BL0, BL1, and BL2 may extend in the second direction D2, may be spaced apart from one another in a first direction D1, and may be arranged 2-dimensionally. Here, the first direction D1, a second direction D2, and a third direction D3 may be orthogonal to one another and may form an orthogonal coordinate system defined by X, Y, and Z axes.

The plurality of cell strings CSTR may be connected in parallel to the bit lines BL0, BL1, and BL2, respectively. The cell strings CSTR may be provided between the bit lines BL0, BL1, and BL2 and one common source line CSL and may be commonly connected to the common source line CSL. At this time, a plurality of common source lines CSL may be provided, and the plurality of common source lines CSL may extend in the first direction D1 and be 2-dimensionally arranged by being spaced apart from one another in the second direction D2. The same electrical voltage may be applied to the plurality of common source lines CSL. However, the present disclosure is not limited thereto, and each of the plurality of common source lines CSL may be electrically independently controlled, and thus different voltages may be applied to the plurality of common source lines CSL, respectively.

The cell strings CSTR may extend in the third direction D3 and be arranged to be spaced apart from one another in the second direction D2 in correspondence to respective bit lines. According to an embodiment, each of the cell strings CSTR may each include a ground select transistor GST connected to the common source line CSL, first and second string select transistors SST1 and SST2 connected in series to the bit lines BL0, BL1, and BL2, and memory cell transistors MCT and an erase control transistor ECT connected in series between the ground select transistor GST and the first and second string select transistors SST1 and SST2. Also, the memory cell transistors MCT may each include a data storage element.

For example, each cell string CSTR may include the first and second string select transistors SST1 and SST2 connected in series, and a second string select transistor SST2 may be connected to one of the bit lines BL0, BL1, and BL2. However, the present disclosure is not limited thereto, and each cell string CSTR may include one string select transistor. In another example, in each cell string CSTR, the ground select transistor GST may include a plurality of MOS transistors connected in series, similarly as the first and second string select transistors SST1 and SST2.

One cell string CSTR may include the plurality of memory cell transistors MCT apart from the common source lines CSL by different distances. In other words, the memory cell transistors MCT may be connected in series while being arranged in the third direction D3 between a first string select transistor SST1 and the ground select transistor GST. The erase control transistor ECT may be connected between the ground select transistor GST and the common source lines CSL. Each cell string CSTR may further include dummy cell transistors DMC connected between the first string select transistor SST1 and the uppermost one of the memory cell transistors MCT and between the ground select transistor GST and the lowermost one of the memory cell transistors MCT.

According to an embodiment, the first string select transistor SST1 may be controlled by first string select lines SSL1-1, SSL1-2, and SSL1-3, and the second string select transistor SST2 may be controlled by second string select lines SSL2-1, SSL2-2, and SSL2-3. The memory cell transistors MCT may be respectively controlled by a plurality of word lines WL0 to WLn, and the dummy cell transistors DMC may each be controlled by a dummy word line DWL. The ground select transistor GST may be controlled by ground select lines GSL0, GSL1, and GSL2, and the erase control transistor ECT may be controlled by an erase control line ECL. A plurality of erase control transistors ECT may be provided. The common source lines CSL may be commonly connected to sources of erase control transistors ECT.

Gate electrodes of the memory cell transistors MCT, which are provided at substantially the same distance from the common source lines CSL, may be commonly connected to one of the word lines WL0 to WLn and DWL and be in an equipotential state. However, the present disclosure is not limited thereto. Even when the gate electrodes of the memory cell transistors MCT are provided at substantially the same level from the common source lines CSL, gate electrodes provided in different rows or columns may be controlled independently.

The ground select lines GSL0, GSL1, and GSL2, the first string select lines SSL1-1, SSL1-2, and SSL1-3, and the second string select lines SSL2-1, SSL2-2, and SSL2-3 extend in the first direction D1 and may be 2-dimensionally arranged by being spaced apart from one another in the second direction D2. The ground select lines GSL0, GSL1, and GSL2, the first string select lines SSL1-1. SSL1-2, and SSL1-3, and the second string select lines SSL2-1, SSL2-2, and SSL2-3 provided at substantially the same level from the common source lines CSL may be electrically separated from one another. Also, the erase control transistors ECT of different cell strings CSTR may be controlled by a common erase control line ECL. The erase control transistors ECT may generate gate induced drain leakage (GIDL) during an erase operation of a memory cell array. According to some embodiments, during an erase operation of a memory cell array, an erase voltage may be applied to the bit lines BL0, BL1, and BL2 and/or the common source lines CSL, and a GIDL current may occur at the string select transistor SST and/or the erase control transistors ECT.

The string select line SSL described above may be referred to as an upper select line USL, and the ground select line GSL may be referred to as a lower select line.

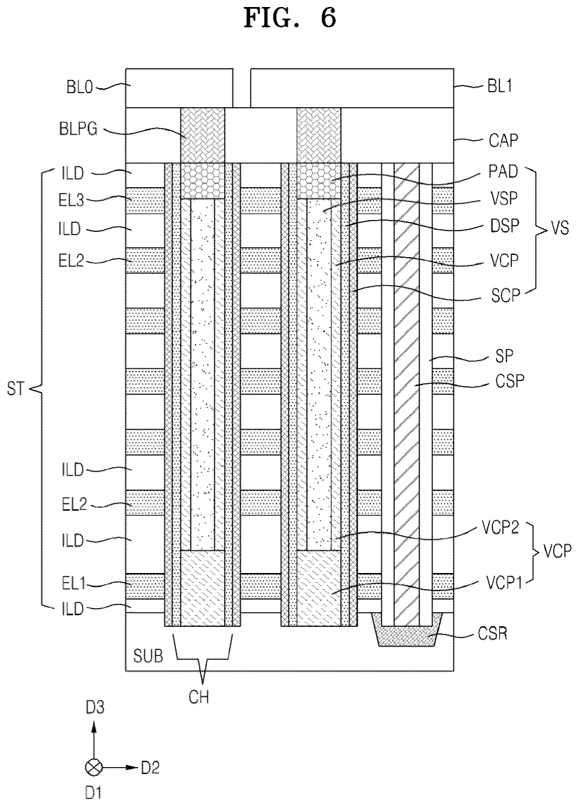

FIG. 6 is a side cross-sectional view of the structure of a 3-dimensional flash memory according to an embodiment.

Referring to FIG. 6, a substrate SUB may include a semiconductor substrate such as a silicon substrate, a silicon-germanium substrate, a germanium substrate, or a single crystal epitaxial layer grown on a monocrystalline silicon substrate. The substrate SUB may be doped with a first conductivity type impurity (e.g., a P-type impurity).

Stacked structures ST may be arranged on the substrate SUB. The stacked structures ST may extend in the first direction D1 and be 2-dimensionally arranged in the second direction D2. Also, the stacked structures ST may be spaced apart from each other in the second direction D2.

The stacked structures ST may each includes gate electrodes EL1, EL2, and EL3 and interlayer insulation layers ILD that are alternately stacked in a vertical direction perpendicular to the top surface of the substrate SUB (e.g., in the third direction D3). The stacked structures ST may each have a substantially flat top surface. In other words, the top surfaces of the stacked structures ST may be parallel to the top surface of the substrate SUB. Hereinafter, the vertical direction refers to the third direction D3 or the reverse direction of the third direction D3.

The gate electrodes EL1, EL2, and EL3 may be one from among the erase control line ECL, the ground select lines GSL0, GSL1, and GSL2, the word lines WL0 to WLn and DWL, the first string select lines SSL1-1, SSL1-2, and SSL1-3, and the second string select lines SSL2-1, SSL2-2, and SSL2-3 that are sequentially stacked on the substrate SUB.

The gate electrodes EL1, EL2, and EL3 may extend in the first direction D1 and have substantially the same thickness in the third direction D3. Hereinafter, the thickness refers to the thickness in the third direction D3. The gate electrodes EL1, EL2, and EL3 may each include a conductive material. For example, the gate electrodes EL1, EL2, and EL3 may each include at least one selected from among a doped semiconductor (e.g., doped silicon, etc.), a metal (e.g., W (tungsten), Cu (copper), Al (aluminum), Ti (titanium), Ta (tantalum), Mo (molybdenum), Ru (ruthenium), Au (gold), etc.) or a conductive metal nitride (e.g., titanium nitride, tantalum nitride, etc.). The gate electrodes EL1, EL2, and EL3 may each include at least one of all metal materials that may be formed through an ALD process in addition to the above-stated metal materials.

In detail, the gate electrodes EL1, EL2, and EL3 may include a first gate electrode EL1, which is the lowermost one, a third gate electrode EL3, which is the uppermost one, and a plurality of second gate electrodes EL2 between the first gate electrode EL1 and the third gate electrode EL3. Although the first gate electrode EL1 and the third gate electrode EL3 are each shown and described in singular form, it is merely illustrative and the present disclosure is not limited thereto. As occasions demand, a plurality of first gate electrodes EL1 and plurality of third gate electrodes EL3 may be provided. The first gate electrode EL1 may correspond to any one of the ground select lines GSL0, GSL1, and GSL2 shown in FIG. 5. A second gate electrode EL2 may correspond to any one of the word lines WL0 to WLn and DWL shown in FIG. 5. The third gate electrode EL3 may correspond to any one of the first string select lines SSL1-1, SSL1-2, and SSL1-3 or the second string select lines SSL2-1, SSL2-2, and SSL2-3 shown in FIG. 5.

Although not shown, an end portion of each of the stacked structures ST may have a stepwise structure in the first direction D1. In detail, the lengths of the gate electrodes EL1, EL2, and EL3 of the stacked structures ST may decrease in the first direction D1 as the distance from the substrate SUB increases. The third gate electrode EL3 may have the smallest length in the first direction D1 and may be the greatest distance apart from the substrate SUB in the third direction D3. The first gate electrode EL1 may have the greatest length in the first direction D1 and may be the smallest distance apart from the substrate SUB in the third direction D3. Due to the stepwise structure, the thickness of each of the stacked structures ST may decrease in a direction away from the outermost one of vertical channel structures VS, which will be described later, and sidewalls of the gate electrodes EL1, EL2, and EL3 may be spaced apart from one another at certain intervals in the first direction D1 when viewed from above.

The interlayer insulation layers ILD may have different thicknesses from one another. For example, the lowermost one and the uppermost one from among the interlayer insulation layers ILD may have smaller thicknesses than the other interlayer insulation layers ILD. However, it is merely an example, and the present disclosure is not limited thereto. The thicknesses of the interlayer insulation layers ILD may be different from or identical to one another depending on the properties of a semiconductor device. The interlayer insulation layers ILD may include an insulation material for insulation between the gate electrodes EL1, EL2, and EL3. For example, the interlayer insulation layers ILD may include silicon oxide.

A plurality of channel holes CH penetrating through the stacked structures ST and portions of the substrate SUB may be provided. The vertical channel structures VS may be provided within the channel holes CH. The vertical channel structures VS may be the plurality of cell strings CSTR shown in FIG. 5, may be connected to the substrate SUB, and may extend in the third direction D3. The vertical channel structures VS may be connected to the substrate SUB as bottom surfaces of portions of the vertical channel structures VS contact the top surface of the substrate SUB. However, the present disclosure is not limited thereto, and the portions of the vertical channel structures VS may also be buried in the substrate SUB. When the portions of the vertical channel structures VS are buried in the substrate SUB, the bottom surfaces of the vertical channel structures VS may be located at a lower level than the top surface of the substrate SUB.

A plurality of columns of the vertical channel structures VS penetrating through any one of the stacked structures ST may be provided. For example, as shown in FIG. 6, three columns of the vertical channel structures VS may penetrate through one of the stacked structures ST. However, the present disclosure is not limited thereto, and two columns of vertical channel structures VS may penetrate through one of the stacked structures ST or four or more columns of the vertical channel structures VS may penetrate through one of the stacked structures ST. In a pair of columns adjacent to each other, the vertical channel structures VS corresponding to one column may be shifted in the first direction D1 from the vertical channel structures VS corresponding to the other column adjacent thereto. When viewed from above, the vertical channel structures VS may be arranged in a zigzag shape in the first direction D1. However, the present disclosure is not limited thereto, and the vertical channel structures VS may be arranged side-by-side in rows and columns.

The vertical channel structures VS may each extend from the substrate SUB in the third direction D3. Although it is shown in the drawing that each of the vertical channel structures VS has a pillar-like shape in which the width thereof at the top is the same as the width thereof at the bottom, the present disclosure is not limited thereto, and the vertical channel structures VS may each have a shape in which the widths in the first direction D1 and the second direction D2 increase in the third direction D3. The top surface of each of the vertical channel structures VS may have a circular shape, an elliptical shape, a rectangular shape, or a bar-like shape.

The vertical channel structures VS may each include a stress control pattern SCP, a data storage pattern DSP, a vertical channel pattern VCP, a vertical semiconductor pattern VSP, and a conductive pad PAD. In each of the vertical channel structures VS, the data storage pattern DSP may have a pipe-like shape or a macaroni-like shape with an open bottom, and the vertical channel pattern VCP may have a pipe-like shape or a macaroni-like shape with a closed bottom. The vertical semiconductor pattern VSP may fill the space surrounded by the vertical channel pattern VCP and the conductive pad PAD.

The data storage pattern DSP may cover the inner wall of each of the channel holes CH, the inner portion of the data storage pattern DSP may surround the outer wall of the vertical channel pattern VCP, and the outer portion of the data storage pattern DSP may contact the gate electrodes EL1, EL2, and EL3. Accordingly, regions of the data storage pattern DSP corresponding to the second gate electrodes EL2 and regions of the vertical channel pattern VCP corresponding to the second gate electrodes EL2 may constitute memory cells on which a memory operation (program operation, read operation, or erase operation) is performed by a voltage applied through the second gate electrodes EL2. The memory cells correspond to the memory cell transistors MCT shown in FIG. 5. To this end, the data storage pattern DSP may include a ferroelectric material to represent a polarization state of charges caused by a voltage applied through the second gate electrodes EL2 into a data value. For example, the ferroelectric-based data storage pattern DSP may represent the polarization states of charge into binary data values or multivalued data values. Hereinafter, the ferroelectric material may include at least one of HfOₓ having an orthorhombic crystal structure, HfOₓ doped with at least one from among Al, Zr, or Si, PZT(Pb(Zr, Ti)O₃), PTO(PbTiO₃), SBT(SrBi₂Ti₂O₃), BLT(Bi(La, Ti)O₃), PLZT(Pb(La, Zr)TiO₃), BST(Bi(Sr. Ti)O₃), barium titanate (BaTiO₃), P(VDF-TrFE), PVDF, AlOₓ, ZnOₓ, TiOₓ, TaOₓ, and InOₓ.

The above-stated ferroelectric-based data storage pattern DSP may exhibit improved orthorhombic properties through a cooling process. Since a 3-dimensional flash memory according to an embodiment is manufactured using a word line replacement process, in order for the ferroelectric-based data storage pattern DSP to improve its orthorhombic properties through a cooling process, a contact membrane is required to generate stress with respect to the data storage pattern DSP. Therefore, in a 3-dimensional flash memory according to an embodiment, the stress control pattern SCP may be used to improve the orthorhombic properties of the ferroelectric-based data storage pattern DSP through a cooling process.

The stress control pattern SCP is formed in contact with the outer wall of the ferroelectric-based data storage pattern DSP, thereby generating stress with respect to the ferroelectric-based data storage pattern DSP during a cooling process to improve the orthorhombic properties of the data storage pattern DSP. For example, the stress control pattern SCP may be formed to extend in the vertical direction (e.g., the third direction D3) so as to be interposed between a stack structure ST (each of the interlayer insulation layers ILD and each of the word lines WL0 to WLn) and the data storage pattern DSP.

As described above, since the stress control pattern SCP has a structure that extends long in the vertical direction (e.g., the third direction D3), the stress control pattern SCP may include a material capable of generating stress with respect to the ferroelectric-based data storage pattern DSP during a cooling process as described above under the condition that the word lines WL0 to WLn do not become conductive to not to be electrically connected through the stress control pattern SCP.

A vertical channel pattern VCP may cover the inner wall of the data storage pattern DSP. The vertical channel pattern VCP may include a first portion VCP1 and a second portion VCP2 on the first portion VCP1.

The first portion VCP1 of the vertical channel pattern VCP may be provided below each of the channel holes CH and may be in contact with the substrate SUB. The first portion VCP1 of the vertical channel pattern VCP may be used to block, suppress, or minimize leakage current in each of the vertical channel structures VS and/or may be used as an epitaxial pattern. For example, the thickness of the first portion VCP1 of the vertical channel pattern VCP may be greater than the thickness of the first gate electrode EL1. The sidewall of the first portion VCP1 of the vertical channel pattern VCP may be surrounded by the data storage pattern DSP. The top surface of the first portion VCP1 of the vertical channel pattern VCP may be located at a higher level than the top surface of the first gate electrode EL1. In detail, the top surface of the first portion VCP1 of the vertical channel pattern VCP may be located between the top surface of the first gate electrode EL1 and the bottom surface of the lowermost one of the second gate electrodes EL2. The bottom surface of the first portion VCP1 of the vertical channel pattern VCP may be located at a lower level than the top surface of the substrate SUB (i.e., the bottom surface of the lowermost one of the interlayer insulation layers ILD). A portion of the first portion VCP1 of the vertical channel pattern VCP may overlap the first gate electrode EL1 in the horizontal direction. Hereinafter, the horizontal direction refers to any direction extending on a plane parallel to the first direction D1 and the second direction D2.

The second portion VCP2 of the vertical channel pattern VCP may extend from the top surface of the first portion VCP1 in the third direction D3. The second portion VCP2 of the vertical channel pattern VCP may be provided between the data storage pattern DSP and the vertical semiconductor pattern VSP and may correspond to the second gate electrodes EL2. Therefore, as described above, the second portion VCP2 of the vertical channel pattern VCP may constitute memory cells together with portions of the data storage pattern DSP corresponding to the second gate electrodes EL2.

The top surface of the second portion VCP2 of the vertical channel pattern VCP may be substantially coplanar with the top surface of the vertical semiconductor pattern VSP. The top surface of the second portion VCP2 of the vertical channel pattern VCP may be located at a higher level than the top surface of the uppermost one of the second gate electrodes EL2. In detail, the top surface of the second portion VCP2 of the vertical channel pattern VCP may be located between the top surface and the bottom surface of the third gate electrode EL3.

The vertical channel pattern VCP may include monocrystalline silicon or polysilicon to form a channel or be boosted by a voltage applied to the data storage pattern DSP. However, the present disclosure is not limited thereto, and the vertical channel pattern VCP may include an oxide semiconductor material that may block, suppress, or minimize leakage current. For example, the vertical channel pattern VCP may include an oxide semiconductor material or a group IV semiconductor material containing at least one of In, Zn, or Ga with excellent leakage current properties. The vertical channel pattern VCP may include, for example, a ZnOₓ-based material including AZO, ZTO, IZO, ITO, IGZO, or Ag—ZnO. Accordingly, the vertical channel pattern VCP may block, suppress, or minimize leakage current to the gate electrodes EL1, EL2, and EL3 or the substrate SUB and improve transistor properties (e.g., threshold voltage distribution and speeds of program/read operations) of at least one of the gate electrodes EL1, EL2, and EL3, thereby improving electrical properties of a 3-dimensional flash memory.

The vertical semiconductor pattern VSP may be surrounded by the second portion VCP2 of the vertical channel pattern VCP. The top surface of the vertical semiconductor pattern VSP may contact the conductive pad PAD, and the bottom surface of the vertical semiconductor pattern VSP may contact the first portion VCP1 of the vertical channel pattern VCP. The vertical semiconductor pattern VSP may be spaced apart from the substrate SUB in the third direction D3. In other words, the vertical semiconductor pattern VSP may be electrically floated from the substrate SUB.

The vertical semiconductor pattern VSP may include a material that helps diffusion of charges or holes in the vertical channel pattern VCP. In detail, the vertical semiconductor pattern VSP may include a material with excellent charge mobility and hole mobility. For example, the vertical semiconductor pattern VSP may include a semiconductor material doped with an impurity, an intrinsic semiconductor material that is not doped with an impurity, or a polycrystalline semiconductor material. As a more specific example, the vertical semiconductor pattern VSP may include polysilicon doped with an impurity of the same first conductivity type (e.g., P-type impurity) as the substrate SUB. In other words, the vertical semiconductor pattern VSP may improve the speed of a memory operation by improving the electrical properties of a 3-dimensional flash memory.

Referring back to FIG. 5, the vertical channel structures VS may correspond to the cell strings CSTR, which are channels of the erase control transistor ECT, the first and second string select transistors SST1 and SST2, the ground select transistor GST, and the memory cell transistors MCT.

Conductive pads PAD may be provided on the top surface of the second portion VCP2 of the vertical channel pattern VCP and the top surface of the vertical semiconductor pattern VSP. The conductive pads PAD may be connected to the top of the vertical channel pattern VCP and the top of the vertical semiconductor pattern VSP. The sidewall of the conductive pad PAD may be surrounded by the data storage pattern DSP. The top surface of the conductive pad PAD may be substantially coplanar with the top surface of each of the stacked structures ST (i.e., the top surface of the uppermost one of the interlayer insulation layers ILD). The bottom surface of the conductive pad PAD may be located at a lower level than the top surface of the third gate electrode EL3. In detail, the bottom surface of the conductive pad PAD may be positioned between the top surface and the bottom surface of the third gate electrode EL3. In other words, at least a portion of the conductive pad PAD may overlap the third gate electrode EL3 in the horizontal direction.

The conductive pad PAD may include a semiconductor material or a conductive material doped with an impurity. For example, the conductive pad PAD may include a semiconductor material doped with an impurity of a conductivity type different from that of the vertical semiconductor pattern VSP (more specifically, a second conductivity type (e.g., an N-type) different from the first conductivity type (e.g., the P-type)).

The conductive pad PAD may reduce contact resistance between the bit line BL and the vertical channel pattern VCP (or the vertical semiconductor pattern VSP), which will be described later.

Although it has been described above that the vertical channel structures VS has a structure including the conductive pad PAD, the present disclosure is not limited thereto, and the vertical channel structures VS may have a structure without the conductive pad PAD. In this case, as the conductive pad PAD is omitted from the vertical channel structures VS, the vertical channel pattern VCP and the vertical semiconductor pattern VSP may each extend in the third direction D3, such that the top surface of each of the vertical channel pattern VCP and the vertical semiconductor pattern VSP is substantially coplanar with the top surface of each of the stacked structures ST (i.e., the top surface of the uppermost one of the interlayer insulation layers ILD). Also, in this case, a bit line contact plug BLPG, which will be described later, may directly contact and be electrically connected to the vertical channel pattern VCP instead of being electrically connected to the vertical channel pattern VCP indirectly through the conductive pad PAD.

Also, although it has been described that the vertical channel structures VS include the vertical semiconductor pattern VSP, the present disclosure is not limited thereto, and the vertical semiconductor pattern VSP may be omitted.

Also, although it has been described that the vertical channel pattern VCP is a structure including the first portion VCP1 and the second portion VCP2, the present disclosure is not limited thereto, and the vertical channel pattern VCP may have a structure excluding the first portion VCP1. For example, the vertical channel pattern VCP may be formed to extend to the substrate SUB to be provided between the vertical semiconductor pattern VSP, which is formed to extend to the substrate SUB, and the data storage pattern DSP and to contact the substrate SUB. In this case, the bottom surface of the vertical channel pattern VCP may be located at a lower level than the top surface of the substrate SUB (the bottom surface of the lowermost one of the interlayer insulation layers ILD), and the top surface of the vertical channel pattern VCP may be substantially coplanar with the top surface of the vertical semiconductor pattern VSP.

An isolation trench TR extending in the first direction D1 may be provided between the stacked structures ST adjacent to each other. A common source region CSR may be provided inside a portion of the substrate SUB exposed by the isolation trench TR. The common source region CSR may extend in the first direction D1 within the substrate SUB. The common source region CSR may include a semiconductor material doped with a second conductivity type impurity (e.g., an N-type impurity). The common source region CSR may correspond to the common source line CSL of FIG. 5.

A common source plug CSP may be provided in the isolation trench TR. The common source plug CSP may be connected to the common source region CSR. The top surface of the common source plug CSP may be substantially coplanar with the top surface of each of the stacked structures ST (i.e., the top surface of the uppermost one of the interlayer insulation layers ILD). The common source plug CSP may have a plate-like shape extending in the first direction D1 and the third direction D3. Here, the common source plug CSP may have a shape whose width in the second direction D2 increases in the third direction D3.

Insulation spacers SP may be interposed between the common source plug CSP and the stacked structures ST. The insulation spacers SP may be provided between the stacked structures ST adjacent to each other to face each other. For example, the insulation spacers SP may include silicon oxide, silicon nitride, silicon oxynitride, or a low-k material with a low dielectric constant.

A capping insulation layer CAP may be provided on the stacked structures ST, the vertical channel structures VS, and the common source plug CSP. The capping insulation layer CAP may cover the top surface of the uppermost one of the interlayer insulation layers ILD, the top surface of the conductive pad PAD, and the top surface of the common source plug CSP. The capping insulation layer CAP may include an insulation material different from that constituting the interlayer insulation layers ILD. The bit line contact plug BLPG electrically connected to the conductive pad PAD may be provided inside the capping insulation layer CAP. The bit line contact plug BLPG may have a shape whose widths in the first direction D1 and the second direction D2 increase in the third direction D3.

The bit line BL may be provided on the capping insulation layer CAP and the bit line contact plug BLPG. The bit line BL corresponds to any one of the plurality of bit lines BL0, BL1, and BL2 shown in FIG. 5 and may include a conductive material to extend in the second direction D2. The conductive material constituting the bit line BL may be the same material as the conductive material constituting each of the gate electrodes EL1, EL2, and EL3 described above.

The bit line BL may be electrically connected to the vertical channel structures VS through the bit line contact plug BLPG. Here, the fact that the bit line BL is connected to the vertical channel structures VS may indicate that the bit line BL is connected to the vertical channel pattern VCP included in the vertical channel structures VS.

A 3-dimensional flash memory having a structure as described above may perform a program operation, a read operation, and an erase operation based on a voltage applied to each of the cell strings CSTR, a voltage applied to the string select line SSL, a voltage applied to each of the word lines WL0 to WLn, a voltage applied to the ground select line GSL, and a voltage applied to the common source line CSL. For example, the 3-dimensional flash memory may perform a program operation by forming a channel in the vertical channel pattern VCP based on a voltage applied to each of the cell strings CSTR, a voltage applied to the string select line SSL, a voltage applied to each of the word lines WL0 to WLn, a voltage applied to the ground select line GSL, and a voltage applied to the common source line CSL and transmitting charges or holes to the data storage pattern DSP of a target memory cell.

Also, a 3-dimensional flash memory according to an embodiment is not limited to the above-stated structure and may be implemented in various structures according to embodiments as long as the 3-dimensional flash memory includes the vertical channel pattern VCP, the data storage pattern DSP, the stress control pattern SCP, the gate electrodes EL1, EL2, and EL3, the bit line BL, and the common source line CSL.

For example, a 3-dimensional flash memory may be implemented with a structure that includes a back gate BG instead of the vertical semiconductor pattern VSP contacting the inner wall of the vertical channel pattern VCP. In this case, the back gate BG may include a conductive material including at least one selected from among a doped semiconductors (e.g., doped silicon, etc.), a metal (e.g., tungsten (W), copper (Cu), aluminum (Al), titanium (Ti), tantalum (Ta), molybdenum (Mo), ruthenium (Ru), gold (Au), etc.), and a conductive metal nitride (e.g., titanium nitride, tantalum nitride, etc.) to be at least partially surrounded by the vertical channel pattern VCP to apply a voltage for a memory operation to the vertical channel pattern VCP and extend.

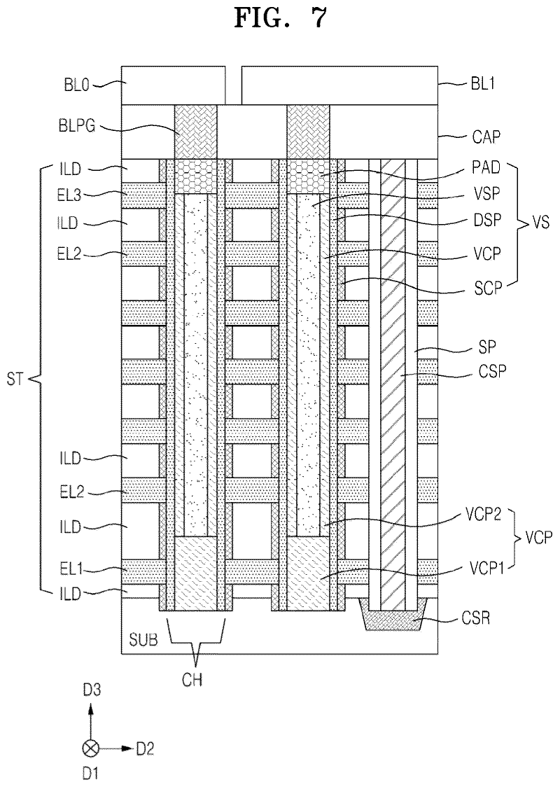

FIG. 7 is a side cross-sectional view of the structure of a 3-dimensional flash memory according to another embodiment.

A 3-dimensional flash memory according to another embodiment described with reference to FIG. 7 has the same structure as the 3-dimensional flash memory according to the embodiment described with reference to FIG. 6, but the structure of the stress control pattern SCP included in each of the vertical channel structures VS is different from that of the 3-dimensional flash memory according to the embodiment described with reference to FIG. 6.

In more detail, the 3-dimensional flash memory of FIG. 7 has the same structure as that of FIG. 6 in that the stress control pattern SCP is formed in contact with the ferroelectric-based data storage pattern DSP to generate stress with respect to the ferroelectric-based data storage pattern DSP during a cooling process. However, unlike the 3-dimensional flash memory of FIG. 6 in which the stress control pattern SCP extends in the vertical direction (e.g., the third direction D3), the 3-dimensional flash memory of FIG. 7 may have a different structure in which the stress control pattern SCP is split to be separated in the vertical direction (e.g., the third direction D3).

For example, the stress control pattern SCP may be formed to be divided into a plurality of parts and to be interposed between each of the interlayer insulation layers ILD and the data storage pattern DSP. The plurality of parts of the stress control pattern SCP correspond to the interlayer insulation layers ILD and may be spaced apart from one another in the vertical direction (the third direction D3).

Likewise, the stress control pattern SCP may include a material capable of generating stress with respect to the ferroelectric-based data storage pattern DSP during a cooling process under the condition that the word lines WL0 to WLn do not become conductive to not to be electrically connected through the stress control pattern SCP.

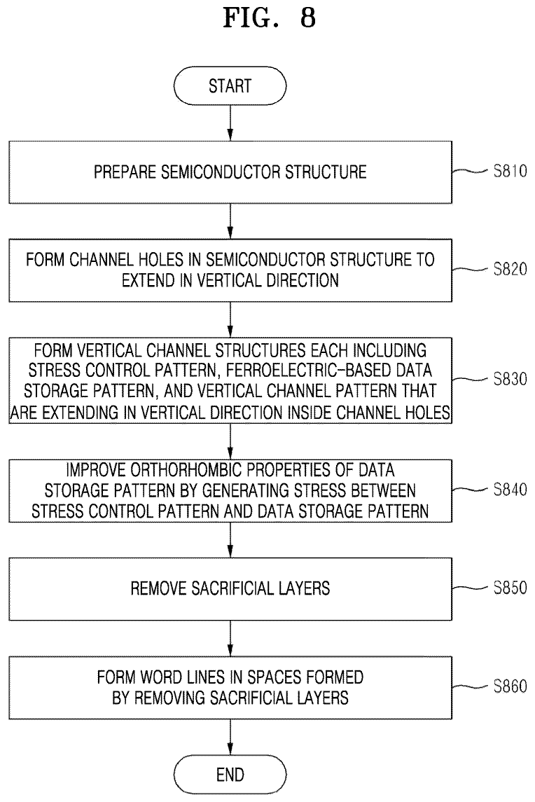

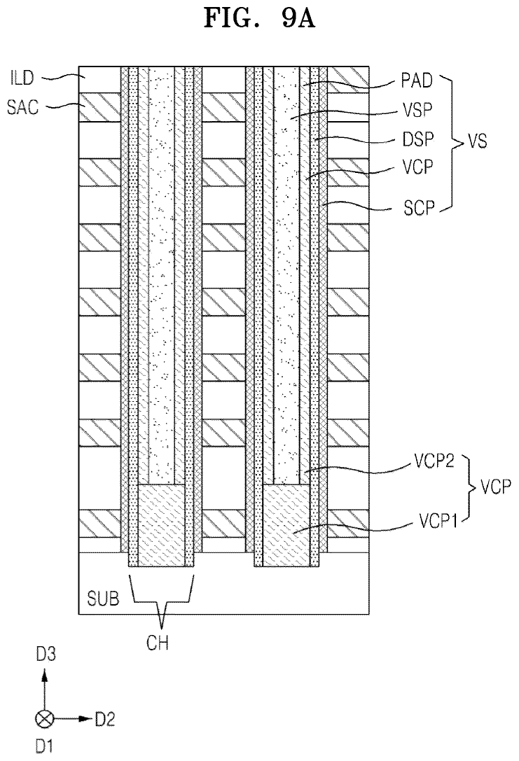

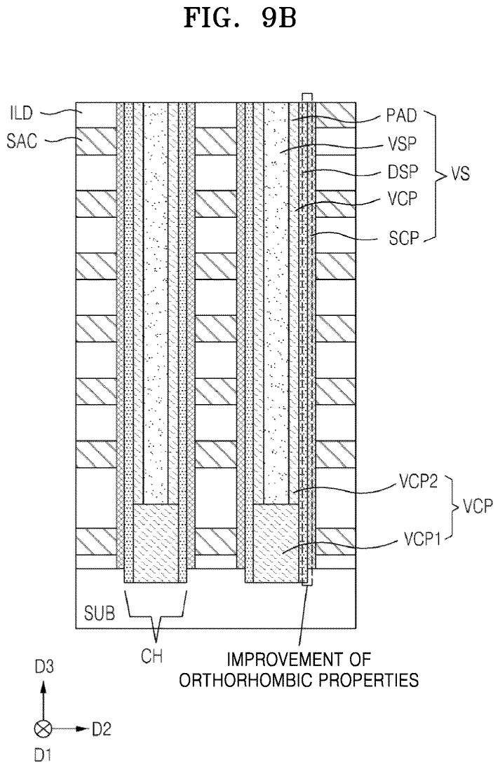

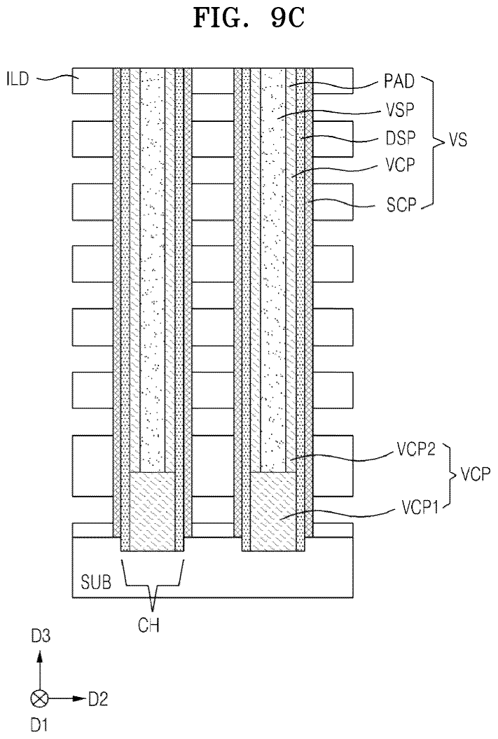

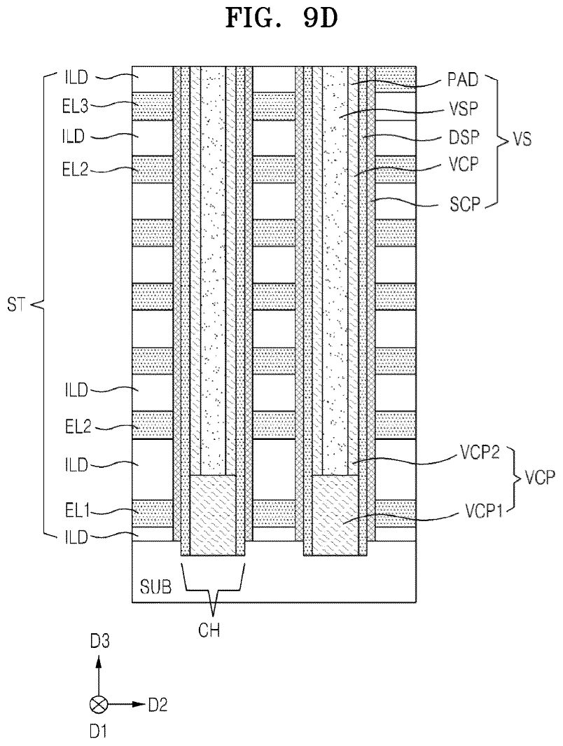

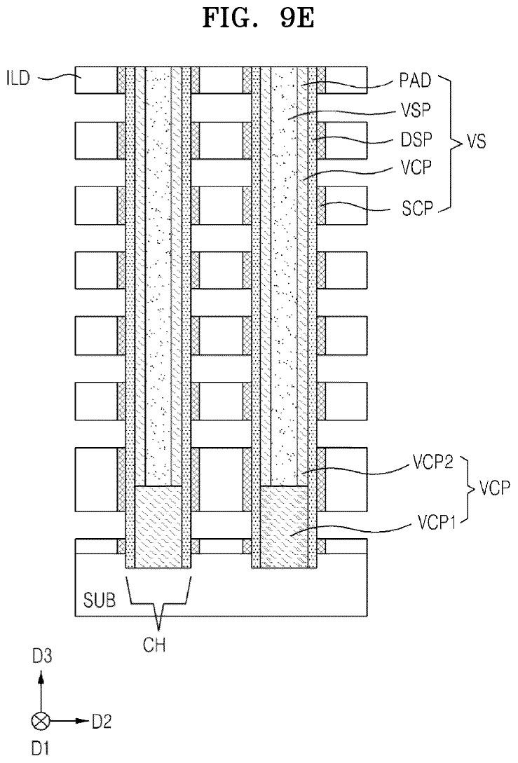

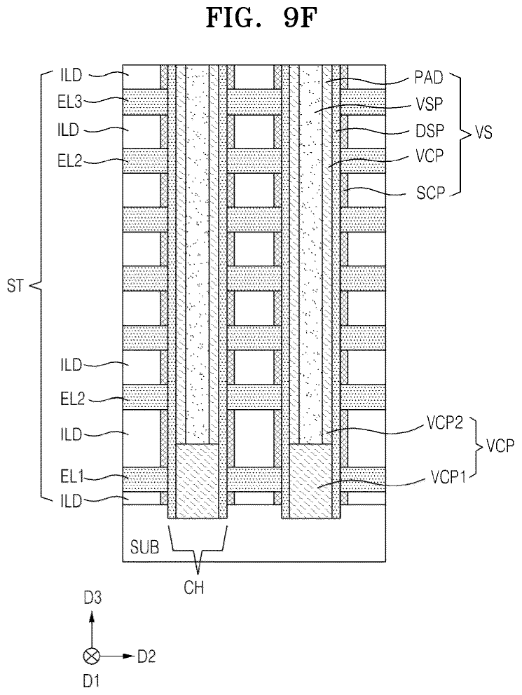

FIG. 8 is a flowchart showing a manufacturing method of a 3-dimensional flash memory according to an embodiment, and FIGS. 9A to 9F are side cross-sectional views of a 3-dimensional flash memory to describe the manufacturing method shown in FIG. 8. Hereinafter, it is assumed that a method for manufacturing a 3-dimensional flash memory according to an embodiment is for manufacturing a 3-dimensional flash memory having the structure described with reference to FIG. 6 and/or the structure described with reference to FIG. 7, using an automated and mechanized manufacturing system. Also, for convenience of explanation, it is described below that the method is to manufacture a 3-dimensional flash memory with a simple structure including the interlayer insulation layers ILD, the word lines WL0 to WLn, and the vertical channel structures VS. Since the materials constituting the components of the 3-dimensional flash memory have been described above with reference to FIGS. 5 and 6, detailed descriptions thereof will be omitted.

In operation S810, a manufacturing system may prepare a semiconductor structure SEMI-STR including the interlayer insulation layers ILD and sacrificial layers SAC formed to extend in horizontal directions (e.g., the first direction D1 and/or the second direction D2) and alternately stacked in a vertical direction (e.g., the third direction D3).

In operation S820, the manufacturing system may form the channel holes CH in the semiconductor structure SEMI-STR to extend in the vertical direction (e.g., the third direction D3).

In operation S830, the manufacturing system may form the vertical channel structures VS each extending in the vertical direction and including the stress control pattern SCP, the ferroelectric-based data storage pattern DSP, and the vertical channel pattern VCP in the channel holes CH.

In operation S840, the manufacturing system may improve the orthorhombic properties of the data storage pattern DSP by generating stress between the stress control pattern SCP and the data storage pattern DSP, as shown in FIG. 9B. For example, the manufacturing system may improve the orthorhombic properties of the data storage pattern DSP by generating stress between the stress control pattern SCP and the data storage pattern DSP through a cooling process.

In operation S850, the manufacturing system may remove the sacrificial layers SAC as shown in FIG. 9C.

In operation S860, the manufacturing system may form the word lines WL0 to WLn in spaces formed by removing the sacrificial layers SAC, as shown in FIG. 9D.

The 3-dimensional flash memory formed through operations S810 to S860 may have a structure in which the stress control pattern SCP extends in the vertical direction, as shown in FIG. 6.

In order for a 3-dimensional flash memory has a structure as shown in FIG. 7 in which the stress control pattern SCP includes a plurality of parts separated from one another in the vertical direction (the third direction D3) in correspondence to the interlayer insulation layers ILD, additional operations need to be performed. For example, the manufacturing system may manufacture a 3-dimensional flash memory having the structure shown in FIG. 7 by removing the sacrificial layers SAC in operation S850, removing portions of the stress control pattern SCP through spaces formed by removing the sacrificial layers SAC, and forming the word lines WL0 to WLn even in spaces formed by removing the portions of the stress control pattern SCP.

Although it has been described above that a 3-dimensional flash memory is manufactured based on a single semiconductor structure, the present disclosure is not limited thereto, and a 3-dimensional flash memory may be manufactured by stacking a plurality of stack structures. In this case, operation S810 may be performed as operation of preparing stack structures each including the interlayer insulation layers ILD and the sacrificial layers SAC extending in the horizontal directions (e.g., the first direction D1 and/or the second direction D2) and alternately stacked in the vertical direction (e.g., the third direction D3), and operation of forming one semiconductor structure by stacking the stack structures may be performed before operation S820. Thereafter, operations S830 to S860 may be performed sequentially.

As described above, although the embodiments have been described with limited examples and drawings, various modifications and variations may be made therein by one of ordinary skill in the art from the above descriptions. For example, appropriate results may be achieved even when the described techniques are performed in a different order than that of the described method and/or components such as systems, structures, apparatuses, circuits, etc. described above are coupled or combined in a different form than those of the described methods or replaced or substituted by other components or equivalents.

Therefore, other implementations, other embodiments, and equivalents of claims also fall within the scope of the claims described below.

1. A method of manufacturing a ferroelectric-based 3-dimensional flash memory, the method comprising:
preparing a semiconductor structure comprising a plurality of word lines extending in a horizontal direction and stacked in a vertical direction on a substrate, a plurality of sacrificial layers interposed between the plurality of word lines and extending in the horizontal direction, and at least one hole formed to extend in the vertical direction and penetrate through the plurality of word lines and the plurality of sacrificial layers, wherein a barrier metal layer extending in the vertical direction is deposited on an inner wall of the at least one hole, and a ferroelectric layer used as a charge storage layer is deposited on an inner wall of the barrier metal layer;
performing a rapid cooling process on the ferroelectric layer in the semiconductor structure;
forming a channel layer to extend in the vertical direction on an inner wall of the ferroelectric layer;
removing the plurality of sacrificial layers; and
forming barrier metal regions isolated from one another by removing portions of the barrier metal layer through spaces formed by removing the plurality of sacrificial layers.

2. The method of claim 1, wherein, in the performing of the rapid cooling process, based on that the ferroelectric properties of the ferroelectric layer, which are improved through the rapid cooling process, is improved in proportion to a contact area of the barrier metal layer in contact with the ferroelectric layer during the rapid cooling process, the rapid cooling process is performed to maximize the ferroelectric properties of the ferroelectric layer through the barrier metal layer in contact with an entire area of one surface of the ferroelectric layer.

3. The method of claim 1, wherein the removing of the plurality of sacrificial layers and the forming of the barrier metal regions isolated from one another are simultaneously performed as removal of the plurality of sacrificial layers and removal of the portions of the barrier metal layer are performed together.

4. The method of claim 1, wherein the forming of the barrier metal regions isolated from one another comprises removing the portions of the barrier metal layer corresponding to the plurality of sacrificial layers among an entire area of the barrier metal layer.

5. The method of claim 1, wherein the removing of the plurality of sacrificial layers comprises forming a plurality of air gaps that insulate the plurality of word lines from one another.

6. A 3-dimensional flash memory comprising:
interlayer insulation layers and word lines extending in horizontal directions and alternately stacked in a vertical direction; and
vertical channel structures extending and penetrating through the interlayer insulation layers and the word lines in the vertical direction, wherein each of the vertical channel structures comprises a vertical channel pattern extending in the vertical direction, a ferroelectric-based data storage pattern surrounding an outer wall of the vertical channel pattern, and a stress control pattern contacting an outer side wall of the data storage pattern,
wherein the stress control pattern is used to generate stress with respect to the data storage pattern so as to improve orthorhombic properties of the data storage pattern.

7. The 3-dimensional flash memory of claim 6, wherein the stress control pattern is formed to extend in the vertical direction to be interposed between each of the interlayer insulation layers and the data storage pattern, and between each of the word lines and the data storage pattern.

8. The 3-dimensional flash memory of claim 6, wherein the stress control pattern is formed in a separated structure in correspondence to the interlayer insulation layers and to be separated in the vertical direction to be interposed between each of the interlayer insulation layers and the data storage pattern.

9. A method of manufacturing a 3-dimensional flash memory, the method comprising:
preparing a semiconductor structure comprising interlayer insulation layers and sacrificial layers extending in horizontal directions and alternately stacked in a vertical direction;
forming channel holes to extend in the vertical direction in the semiconductor structure;
forming vertical channel structures to extend in the vertical direction, the vertical channel structures each comprising a stress control pattern, a ferroelectric-based data storage pattern, and a vertical channel pattern, in the channel holes;
improving orthorhombic properties of the data storage pattern by generating stress between the stress control pattern and the data storage pattern;
removing the sacrificial layers; and
forming word lines in spaces formed by removing the sacrificial layers.

10. The method of claim 9, wherein the removing of the sacrificial layers comprises removing portions of the stress control pattern through the spaces formed by removing the sacrificial layers, and
the forming of the word lines comprises forming the word lines even in spaces formed by removing the portions of the stress control pattern.
